(19) United States
(12) Patent Application Publication
(10) Pub. No.: US 2012/0048376 A1
(43) Pub. Date: Mar. 1, 2012

(54) Silicon-based photovoltaic device produced by essentially electrical means

(75) Inventor: Boris Gilman, Mountain View, CA (US)

(73) Assignee: Alexander SHKOLNIK

(21) Appl. No.: 12/807,143

(22) Filed: Aug. 30, 2010

(51) Int. Cl. H01L 31/028

(52) U.S. Cl. 136/261

(57) ABSTRACT

A photovoltaic device that includes a silicon substrate, selective emitters and field-induced emitters (inversion type) on one side of a silicon substrate; selective back-surface field (BSF) regions or front-surface field (FSF) regions on the other side of the silicon substrate (accumulation-type regions), insulating films on both sides of the silicon substrate, fixed charges of the opposite signs on the opposite sides of the silicon substrate built in the insulating films, respectively, and self-aligned contact regions at least to the selective emitters. A majority of the aforementioned components are produced only by essentially electrical means and without conventional thermal diffusion and masking processes. Entire devices can be manufactured according to a simple method and are characterized by high efficiency, reduced cost, and increased throughput in the field of solar cell fabrication.

### FIELD OF THE INVENTION

The invention relates to monocrystalline, polycrystalline, or microcrystalline silicon-based semiconductor devices, particularly photovoltaic devices such as solar cells. More specifically, the invention relates to photovoltaic devices having selective emitters, field-induced emitters, back-surface field regions, and contacts to functional regions formed by essentially electrical means and without conventional thermal diffusion and masking processes. The proposed devices can be manufactured by a simple method and are characterized by high efficiency, reduced cost, and increased throughput in the field of solar cell fabrication.

### BACKGROUND OF THE INVENTION

At the present time solar cells are classified into three generations, which are described below.

First-generation solar cells are silicon-based solar cells that dominate the solar market (80 to 90%). Solar cells of this type are manufactured of monocrystalline or polycrystalline silicon, and, in spite of high manufacturing cost (typically ranging from $3/W to $5/W, which is much higher than is required for wide implementation), popularity of these solar cells results from their high efficiency, well developed processing, and practically unlimited availability of silicon.

Solar cells of the second generation are also known as thin-film solar cells. The cells of this type are less expensive, lighter in weight, and more attractive in appearance than solar cells of the first generation. However, they are less efficient than first-generation cells.

Third-generation solar cells do not need the doped p-n junction necessary in traditional silicon-based and thin film cells. Third-generation cells contain a wide range of potential solar innovations, including polymer-based solar cells, nanocrystalline, nanomaterial-based cells, and dye-sensitized solar cells.

Irrespective of a provision of later generations, interest in solar cells of the first generation remains very keen, and research in this direction continues.

Typically, a silicon-based solar cell, i.e., a solar cell of the first generation, comprises a large-area p-n junction made of silicon. In such a solar cell, p-n junctions are typically formed by diffusion, e.g., of an n-type dopant into one side of a p-type wafer. When the solar cell of the first generation is irradiated with solar rays, electrons and holes move across and are separated by the p-n junction to generate photocurrent.

Several examples of inventions aimed at improvement of silicon-based photovoltaic cells of the first generation are given below.

U.S. Patent Application Publication No. 20050133084 published on Jun. 23, 2005 (inventors: Toshio Joge, et al) describes a silicon solar cell with n<+>pp<+>structure using solar-grade silicon substrate. The solar cell is produced by a back-side boron diffusion step for diffusing boron on the back side of a substrate, a front-side phosphorus diffusion step for diffusing phosphorus on the front side of a substrate, a low-temperature annealing step for annealing the substrate at a temperature not exceeding 600° C. for at least 1 hour, and an electrode firing step carried out at a peak temperature of less than 700° C. for less than 1 minute. All of these steps are performed in the same sequence as they are mentioned above.

Japanese Unexamined Patent Application Publication (Kokai) 2005183469 published on Jul. 7, 2005 (inventor: Hagino Kimito) discloses a solar cell provided with a silicon substrate of a first polarity and a silicon nitride film of a second polarity, which is formed on the surface of a light-receiving side. In the manufacturing method of the solar cell, the silicon nitride film corresponding to a charge state on the light-receiving side and the rear side of the cell is formed. Thus, the lifetime of minority carriers in a wafer bulk is improved, recombination of optically generated carriers near a wafer surface is reduced, and the cell is improved with a fixed-charge effect on the silicon nitride film.

U.S. Patent Application Publication No. 20100084009 published on Apr. 8, 2010 (inventors: David Carlson, et al) describes a photovoltaic cell comprising a semiconductor wafer having a front light-receiving surface and an opposite back surface, a passivation layer on at least the back surface, a doped layer opposite in conductivity type to the wafer over the passivation layer, an induced inversion layer, a dielectric layer over the doped layer, and one or more localized emitter contacts and one or more localized base contacts on at least the back surface extending at least through the dielectric layer.

According to another embodiment, the invention discloses a neutral-surface photovoltaic cell comprising a semiconductor wafer having a front, light-receiving surface and an opposite back surface, a neutral passivation layer on at least the back surface, a dielectric layer over the passivation layer, and one or more localized emitter contacts and one or more localized base contacts on at least the back surface extending at least through the dielectric layer.

U.S. Patent Application Publication No. 20050022863 published on Feb. 3, 2005 (inventors: Guido Agostinelli, et al) discloses a method for dielectrically passivating the surface of a solar cell by accumulating negative fixed charges at the interface between the semiconductor material and a passivating material. The passivating material comprises an oxide system, for example a binary oxide system, comprising Al₂O₃ and at least one metal oxide or metalloid oxide that enhances the tetrahedral structure of Al₂O₃, for example, an (Al₂O₃)ₓ(TiO₂)₁₋ₓ alloy. In this way, it is possible to combine the desirable properties from at least two different oxides while eliminating the undesirable properties of each individual material. The oxide system can be deposited onto the semiconductor surface by means of a sol-gel method, comprising the steps of formation of the metal oxide and/or metalloid oxide sol and the aluminum solution and then carefully mixing these together under stirring and ultrasonic treatment. Thin films of the oxide system can then be deposited onto the semiconductor surface by means of spin coating followed by a temperature treatment.

Bulgarian Patent No. BG109881 issued on Dec. 30, 2008 to Petko Vitanov, et al, describes a solar cell with a field-induced emitter in the form of an inversion layer wherein the front-side emitter is formed by an electric field generated by an electric charge developed in a dielectric antireflective coating on the front surface of the solar cell. However, this type of cell requires formation of selective N+doped emitters and back-surface field (BSF) regions (needed to provide contact regions for photocurrent) by means of conventional high-temperature diffusion.

The article “Light-Efficiency Solar Cells Based on Inversion Layer Emitters” by I. Martin, et al, (24th European Photovoltaic Solar Energy Conference, 21-25 Sep. 2009, Hamburg, Germany) describes inversion layer emitters that have been proposed for use in crystalline silicon (c-Si) solar cells based on p-type substrates as an alternative to high-temperature phosphorus diffusion. According to this article, a dielectric film deposition at low temperature (<400° C.) is widely used for c-Si surface passivation, and in this case emitters are induced by the positive fixed charge, Qt, at the c-Si/dielectric interface. In their study, the authors used 2-D simulations to explore solar cell structures with inversion layer emitters placed between local n+-emitters. The local diffusions could be defined by laser processing, resulting in potentially low-temperature processed structures. From simulation results, the low conductivity of inversion layer emitters requires a short contact spacing and, hence, dense front grids and high shadow losses. However, placing the emitter at the back reduces these penalties, increasing the efficiency approximately 1% absolute. Furthermore, taking advantage of the fully metallized back surface, inversion layer emitters can be assisted by the work function difference between the c-Si substrate and the metal (typically aluminum) over the dielectric. As a result, the necessity of a high positive Qt value can be relaxed.

### SUMMARY

The present invention provides a solar cell structure that includes at least the following indispensable components: a silicon substrate; selective emitters and field-induced emitters (inversion type) on a first side of the silicon substrate; selective back-surface field (BSF) regions or front-surface field (FSF) regions on the second side of the silicon substrate (accumulation type of regions); insulating films on both sides of the silicon substrate; fixed charges of the opposite signs on the opposite sides of the silicon substrate built in the insulating films, respectively; and self-aligned contact regions at least to the selective emitters.

A solar cell of such a structure that contains all aforementioned components combined into a single unit or cell can be produced only by essentially electrical means and without conventional thermal diffusion and masking processes, i.e., by means of a method that is described in my co-pending U.S. patent application Ser. No. 12/804,655 filed Jul. 28, 2010. The process includes forming conductive layers on both sides of an intermediate solar-cell structure, performing electrical and thermal treatment by passing electrical current independently through the front-side conductive layer and the back-side conductive layer, thus forming selective emitters, selective BSF regions, selective emitter contact regions, and contacts to the selective BSF regions. The obtained structure is then subjected to pulse electrical treatment by applying a voltage pulse or pulses between the front and back conductive layers to form the field-induced emitter (inversion) and the field-induced BSF region (accumulation). After the conductive layers are removed, a final solar cell is obtained.

A solar cell of the invention is less expensive than solar cells manufactured by conventional methods that involve furnace-based thermal diffusion and photolithography or other high-temperature and patterning operations.

Although the aforementioned conductive layers are technological, i.e., temporary components, they play an essential role in manufacture and structure of the solar cell. They are needed for electrical and thermal treatment, but at least the front-side conductive layer has to be removed in order to form the final solar cell. The magnitude of current that is passed through the conductive layers is selected so as to heat the treated layers to the temperature needed to cause diffusion of the dopant from the dopant-containing regions on the front side and from the direct-contact regions on the back side into the silicon substrate. As a result of the elevated temperature that is developed during resistive heating, the dopants further diffuse into the silicon substrate, thus forming selective emitters on the front side and selective BSF regions on the back side.

According to one aspect of the invention, a conductive layer formed on the back side of the cell may remain in the final structure and can be used in the solar cell as a back-side electrode and a back reflector.

According to another aspect of the invention, a front-side solar cell can be made as a so-called transparent solar cell, in which after fulfilling their essential function both the front-side conductive layer and the back-side conductive layer are removed. As a result, local electrodes for the selective BSF regions are formed and are intended to function as back-side self-aligned electrodes.

### BRIEF DESCRIPTION OF THE DRAWINGS

FIG. 1 is a cross-sectional structure of a front-side solar cell according to one aspect of the invention, wherein the back-side conductive layer remains in the solar cell for use as a back-side electrode and a back reflector.

FIG. 2 is a cross-sectional structure of a front-side transparent solar cell according to another aspect of the invention in which both the front-side conductive layer and the back-side conductive layer are removed.

FIGS. 3 to 13 illustrate a method of manufacturing the front-side solar cells of the invention, wherein FIG. 3 illustrates Step 1, in which a silicon substrate is provided and a dopant substance is applied in the form of dots or stripes (here and hereinafter the structures are shown in cross sections).

FIG. 4 illustrates Step 2, in which initial sintering of the dopant substance is carried out.

FIG. 5 illustrates Step 3, in which thin silicon oxide (SiO₂) layers are grown on the front side and on the back side of the substrate, respectively.

FIG. 6 shows Step 4, in which silicon nitride (Si₃N₄) film is deposited onto the entire front SiO₂ layer and the entire back SiO₂ layer. The front thin silicon oxide (SiO₂) layers and the front silicon nitride film form a front-side insulating film that functions in the final device as antireflective coating.

FIG. 7 shows Step 5, in which windows are formed on the front side of the insulating film.

FIG. 8 illustrates Step 6, in which windows are formed on the back side of the insulating film of the initial device structure.

FIG. 9 illustrates Step 7, in which stacked conductive metal layers or metal-containing conductive paste layers are applied onto the front and back surfaces of the initial device structure.

FIG. 10 illustrates Step 8, which is a unique electrical and thermal treatment of the initial device structure in which electrical currents independently pass through the front-side conductive layer and the back-side conductive layer.

FIG. 11 is a cross-sectional view of the intermediate device obtained after critical Step 8.

FIG. 12 illustrates Step 9, which is a pulse electrical treatment of the structure in FIG. 11 (for simplicity of the drawings in FIG. 11 and in subsequent drawings, the current-supply and heat-insulating fixtures are not shown).

FIG. 13 is a sectional view of the device formed after completion of the pulse electrical treatment.

### DETAILED DESCRIPTION OF THE INVENTION

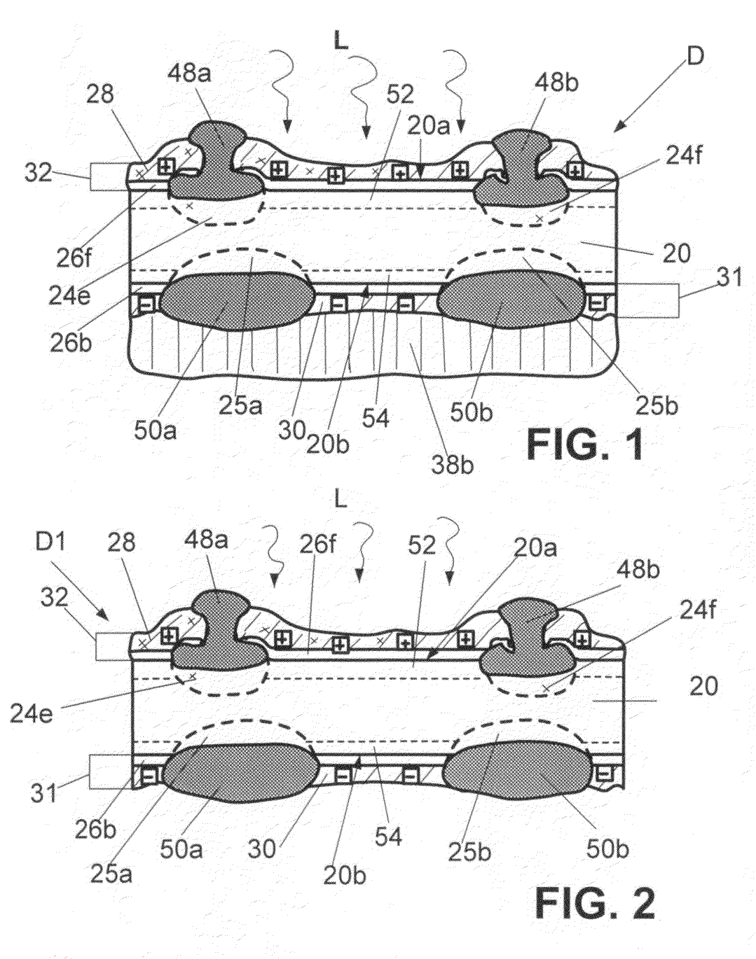

One example of a silicon-based photovoltaic device of the invention (hereinafter referred to as PV device D) is shown in FIG. 1, and another example of the device of the invention (hereinafter referred to as PV device D1) is shown in FIG. 2, where FIG. 1 and FIG. 2 are cross-sectional views of the respective devices. Because FIGS. 1 and 2 are used in this specification for description not only of the device structures but also of the last steps in device manufacture, some references numerals shown in these drawings are not mentioned in the description of the respective devices but are mentioned later in connection with the description of the manufacturing method.

The PV device, which in FIG. 1 is designated as a whole by symbol D, comprises a silicon substrate 20 that has a front side 20a and a back side 20b, a front-side insulating film 32, which is formed on the surface of the front side 20a, a field-induced emitter 52 (inversion layer) formed inside the substrate 20 underneath the surface of the front side 20a, selective emitters 24e and 24f (although only two selective emitters are shown in FIG. 1, the number of selective emitters may be greater than two) which are also positioned under the surface of the front side 20a, and contact regions 48a and 48b to the selective emitters 24e and 24f, respectively.

The front-side insulating film 32 consists, e.g., of a thin silicon oxide (SiO₂) layer 26f and a silicon nitride (Si₃N₄) layer 28. The silicon nitride layer 28 contains a fixed electrical charge, which is positive if the silicon substrate 20 is a P-type substrate. In the example in FIG. 1, the silicon substrate is a P-type substrate, and the charge is positive and is shown by small square boxes with pluses.

The PV device D shown in FIG. 1 further comprises a back-side insulating film 31, which is formed on the surface of the back side 20b, a field-induced back surface field (BSF) region 54 (accumulation layer) formed inside the substrate 20 over the surface of the back side 20b, selective BSF regions 25a and 25b (although only two selective BSF regions are shown in FIG. 1, the number of these regions may be greater than two), and contact regions 50a and 50b to the selective BSF regions 25a and 25b, respectively.

The back-side insulating film 31 consists, e.g., of a thin silicon oxide (SiO₂) layer 26b and a silicon nitride (Si₃N₄) layer 30. The silicon nitride layer 30 contains a fixed electrical charge, which is negative if the silicon substrate 20 is a P-type substrate. In the example of FIG. 1, the silicon substrate is a P-type substrate, and the charge is negative and is shown by small square boxes with minus signs.

The PV device D of the type shown in FIG. 1 is also provided with a continuous conductive layer 38b that covers the entire back side of the PV device D. The layer 38b is used as a back-side electrode and a back reflector.

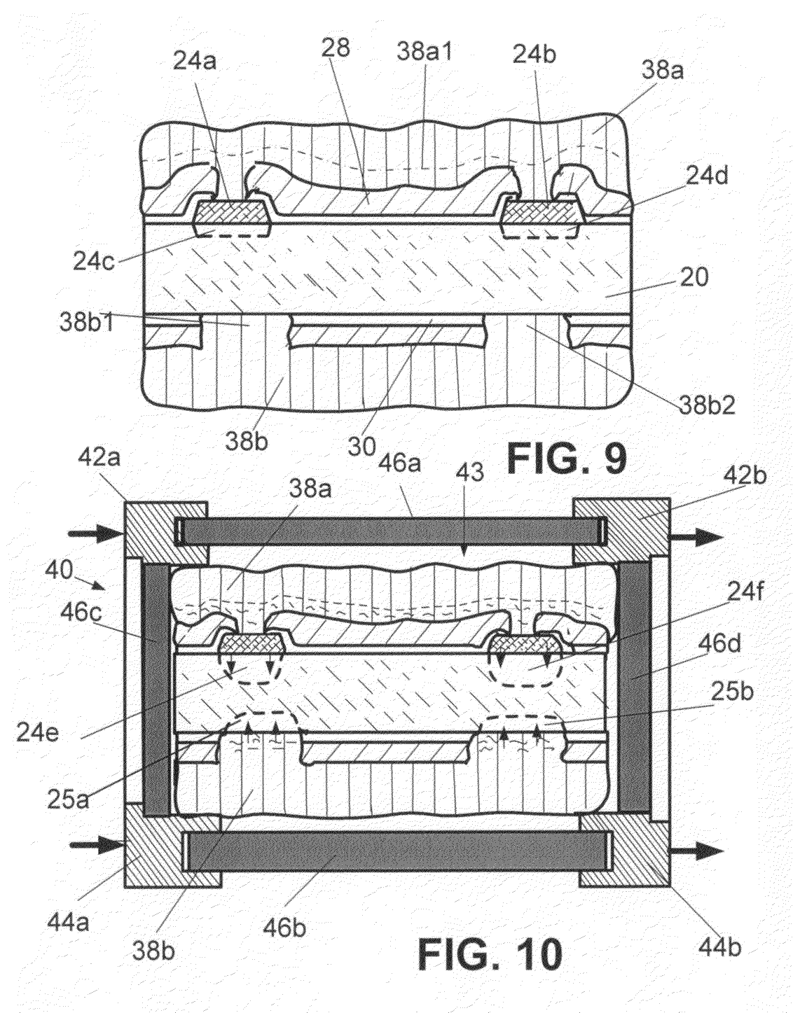

The selective emitters 24e and 24f shown in the PV device D in FIG. 1 comprise heavily doped regions, which in the illustrated example are N-type regions that are formed as a result of doping, e.g., of phosphorus, into the silicon substrate 20 under the effect of a resistive heating of a dopant substance predeposited onto the front side 20a of the substrate. The resistive heating results from passing an electrical current through a front-side conductive layer 38a (see FIG. 9 relating to the method of manufacturing the PV device D) that is temporarily formed on the front side of the PV device D for this purpose. The second purpose of the temporary front-side conductive layer 38a is to form the contact regions 48a and 48b to the selective emitters 24e and 24f. The regions 48a and 48b are formed as an alloy, e.g., of doped silicon with a metal of the front-side conductive layer 38a.

The conductive layer 38a used for the front side may contain a metal such as silver, aluminum, titanium, palladium, nickel, or their combinations and is typically deposited (evaporated) onto the front side 20a of the substrate 20 in the form of a stack, e.g., Ti—Ag, Ti—Pd—Ag, and Ni—Cr, etc. The conductive layer 38a may have a thickness ranging from 1 to 5 μm.

The selective BSF regions 25a and 25b shown in the PV device D in FIG. 1 comprise heavily doped regions, which in the illustrated example are P-type regions that are formed as a result of doping, e.g., of aluminum or boron, into the silicon substrate 20 under the effect of a resistive heating of the material on the back-side conductive layer 38b, the heating resulting from passing an electrical current through the back-side conductive layer 38b (see FIG. 9 regarding method of manufacturing PV device D).

In the example of the PV device D shown in FIG. 1, the back-side conductive layer 38b remains in the device structure and, as mentioned above, functions as a back-side electrode and a back reflector.

Another function of the back-side conductive layer 38b is to form the contact regions 50a and 50b to the selective BSF regions 25a and 25b. The regions 50a and 50b are formed as an alloy, e.g., of doped silicon with a metal of the back-side conductive layer 38b.

The conductive layer 38b used for the back side 20b may include metal layers of Al or Al—Ag, Al—Si, Al—Ag conductive paste, or the like. Compositions of the conductive layers on the front side and on the back side can be different, and these layers can be deposited simultaneously or in sequence. The conductive layer 38b may have a thickness in the range of 1 to 5 μm. The back-side conductive layer contains elements that during electrical and thermal treatment function as a back-side dopant to form selective BSF regions.

FIG. 2 is a cross-sectional structure of a PV device according to another aspect of the invention. In general, this PV device, which as a whole is designated by symbol D1, is the same as the PV device D in FIG. 1 and differs from the PV device D in that it does not contain the back-side conductive layer 38b and its back-side insulating film 31 is exposed. Since, except for the absence of the conductive layer, the remaining structure of the PV device D1 remains the same as the respective structure of the PV device D, such components as the substrate 20, the selective emitters 24e and 24f, the front-side insulating film 32, etc., remain the same and therefore are designated by the same reference numerals. However, removal of the back-side conductive layer 38b turns the contacts 50a and 50b into local self-aligned electrodes that function as back-side electrodes.

It should be noted that some specific and unique features inherent in the PV devices D and D1 result from the unique method of their manufacturing. In fact, the devices D and D1 can be efficiently produced only by means of the method described, which is the subject of our co-pending U.S. patent application Ser. No. 12/804,655 filed Jul. 28, 2010.

Operation of the PV devices D and D1 of the invention will be further described with reference to the devices of both modifications (FIG. 1 and FIG. 2).

When solar light L falls onto the front side of the device D, the light L is absorbed by the silicon substrate 20, whereby electrons and holes are generated and move in the silicon substrate 20 so that electrons are collected by the emitter regions and holes are collected by the BSF regions. As a result, electrical charges of opposite signs are created on the contact regions 48a, 48b and 50a, 50b, respectively. This results in electrical current and voltage, thus producing an electric power.

Since the field-induced emitter 52 comprises a very thin inversion layer (e.g., less than 100 Angstroms) that continues into the substrate in the form of a depletion region (not shown) that includes a high electric field, it becomes possible to improve carrier collection efficiency for those carriers that are generated at or close to the front-side surface 20a of the substrate. Another contribution to improvement in device efficiency is provided by high-quality passivation of the front-side surface 20a by the silicon oxide layer 26f.

Furthermore, the surface recombination rate is significantly reduced on both front-side and back-side surfaces due to the presence of the electrical field at the surfaces. This further improves quantum efficiency of the present device. Additionally, due to the possibility of achieving extremely high values of the positive electrical charge in the front-side insulating film 32, the sheet resistivity of the field-induced emitter (i.e., of the inversion layer) is lower than the known average. This allows increased distances between the selective emitters 24e and 24f and between contact regions 48a and 48b and thus reduces shadowed portions of the front-side surface 20a and further improves efficiency of the device.

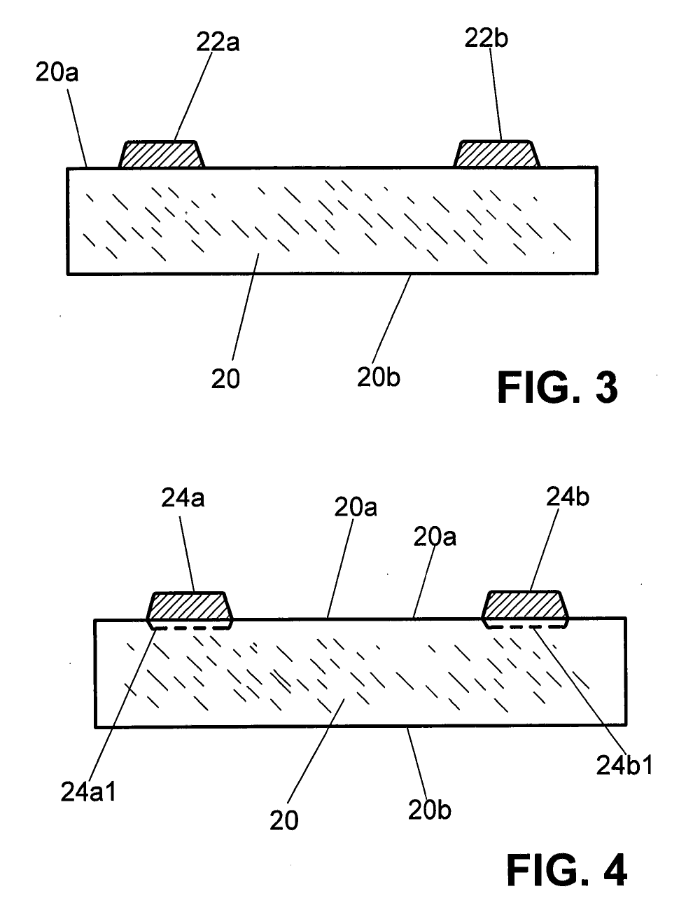

To better understand the structure of the PV devices D and D1, the method of manufacturing the photovoltaic device of the invention, which is incorporated herein by reference, is described below in detail. The method is described in the form of sequential manufacturing steps with reference to attached drawings (FIGS. 3 to 13). In these drawings, the substrate and other elements of the solar cell are shown in cross section.

Step 1 of the method is shown in FIG. 3. In this step a substrate 20 made of monocrystalline silicon is provided, and a dopant substance is applied. The substrate 20 can be a P-type substrate, can have a thickness in the range of 200 to 300 μm, and can have a resistivity ranging from 1 to 10 Ohm·cm. The front side 20a of the substrate 20 can be textured (not shown). Reference numeral 20b designates the back side of the substrate 20. A dopant substance is applied onto the front side 20a of the substrate 20 to form local dot-like or stripe-like dopant-containing regions 22a and 22b. The dopant substance may comprise, e.g., phosphorus-doped nanoparticles (as described in U.S. Pat. No. 7,615,393 published Nov. 10, 2009; inventors: S. Shah, et al.) or a phosphorus-containing paste applied by screen printing or jet printing. The dopant-containing stripes may have a thickness in the range of 400 to 800 nm and a width of 100 to 200 μm. The local dots or stripes 22a and 22b are applied onto areas where selective emitters of the solar cell are to be formed in subsequent steps.

Step 2, which is shown in FIG. 4, is an initial sintering of the dopant substance shown in FIG. 3 in the form of dots or stripes 22a and 22b. Sintering, which is used to solidify dopant-containing regions, can be carried out in ambient atmosphere at a temperature in the range of 700° C. to 900° C. for a short time, e.g., between 5 and 20 sec. It is understood that specific parameters for initial sintering need to be optimized for each particular dopant substance. As a result, sintered dopant-containing regions 24a and 24b are formed on the front side 20a of the substrate, and very shallow low-doped N-regions 24a1 and 24b1 can be formed under the sintered dopant-containing regions 24a and 24b, respectively. In other words, low-doped selective-emitter regions are formed. This step can be carried out by rapid thermal annealing (RTA) or in a similar nonvacuum chamber, e.g., in the atmosphere of nitrogen.

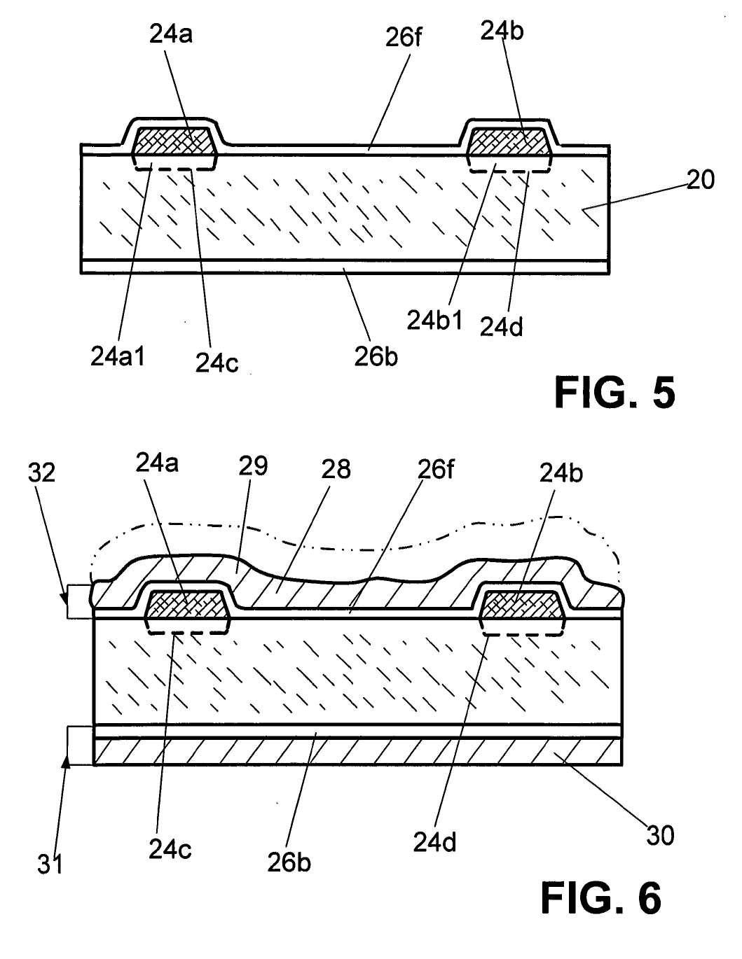

Step 3, which is shown in FIG. 5, comprises growing thin silicon oxide (SiO₂) layers 26f and 26b on the front side 20a and on the back side 20b of the substrate 20, respectively. The purpose of the SiO₂ layers is to reliably passivate the front-side and back-side surfaces, to create controlled hole injection (for the front-side 20a) and electron injection (for the back-side 20b), and to generate a charged retention barrier, which may be required for dielectric charging in subsequent pulse electrical treatment (Step 9 which is described later). In the structure of the solar cell, the front-side SiO₂ layer 26f also functions as part of an antireflective coating, which, as shown later, includes silicon nitride. Oxidation causes further diffusion of phosphorus from the dopant-containing regions 24a and 24b into the silicon substrate. The zones of deeper penetration of the phosphorus into the silicon, which are shown in FIG. 3 by broken lines 24c and 24d, designate starting areas for the formation of selective emitters.

In Step 6, shown in FIG. 4, a silicon nitride (Si₃N₄) film 28 is deposited onto the entire front SiO₂ layer 26f, and a Si₃N₄ film 30 is deposited onto the entire back SiO₂ layer 26b. The film can be deposited, e.g., by means of chemical vapor deposition. In combination with the SiO₂ layer on the front side of the substrate 20, the nitride film 28 forms a front-side insulating film 32 that functions as an antireflective coating. In combination with the SiO₂ layer 26b on the back side of the substrate 20, the nitride film 30 forms a back-side insulating film 31 that functions as back-side passivation (and back-reflection support for modifications to the solar cell with a back-side reflector, which is shown in FIG. 12 and is described below). The nitride film can have a thickness in the range of 65 to 75 nm. Alternatively, the thickness may be in the range of 210 to 230 nm. The deposition temperature may be, e.g., in the range of 350 to 450° C. Alternatively, the nitride film can be deposited only onto the front SiO₂ layer 26f. To protect the front and back surfaces from potential penetration of metal atoms during subsequent steps in forming selective emitters, the initial thickness of the Si₃N₄ film may be greater than the upper limit of the above range. Therefore, an additional step of thinning the film to the range, e.g., of 65 to 75 nm, may be required at the end of the process. Alternatively, at this step an additional insulating film 29, e.g., of SiO₂, can be deposited on top of the Si₃N₄ film 28. This additional film is removed at the end of the process.

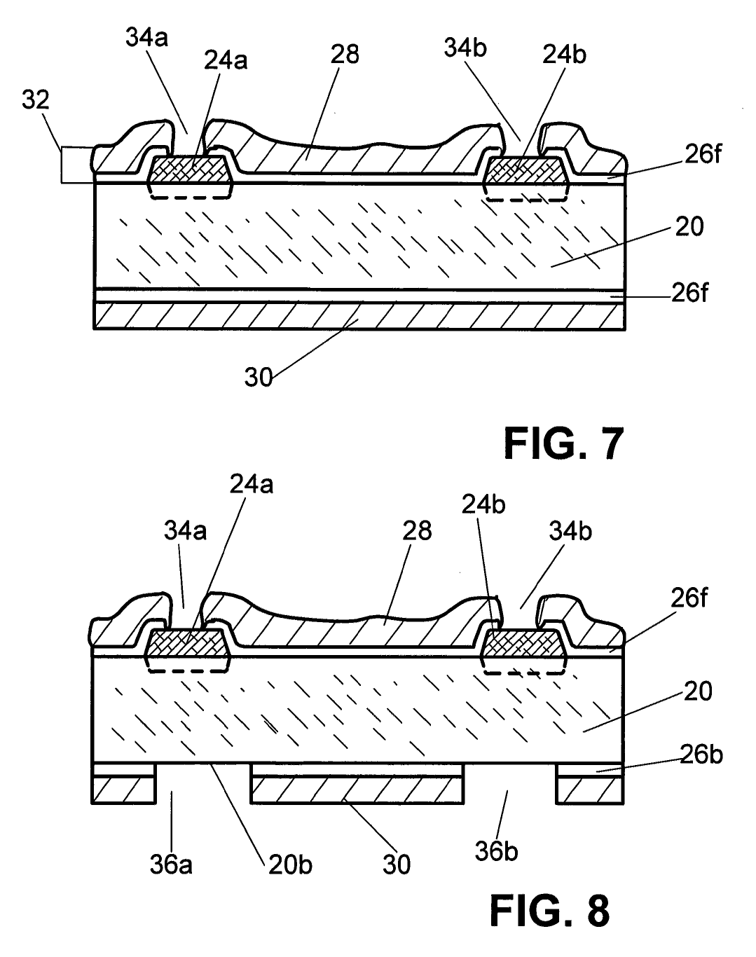

Step 5, which is shown in FIG. 7, is aimed at forming front windows 34a and 34b in the front-side insulating film 32 on the front side of the cell in the initial device structure. Since the positions of the dopant-containing regions 24a and 24b can be seen through the front-side insulating film 32, which is transparent and in view of a significant thickness and relatively large lateral size of dopant-containing regions 24a and 24b, the front windows 34a and 34b can be cut, e.g., by means of a laser (as described in U.S. Pat. No. 6,426,235 issued on Jul. 30, 2002 to T. Matsushita, et al), or, alternatively, a single photolithography step may be required to form the windows. The front windows 34a and 34b may have a width, e.g., in the range of 10 to 20 μm.

Step 6, which is shown in FIG. 8, comprises formation of back windows 36a and 36b on the back side of the structure shown in FIG. 5. The back windows 36a and 36b are cut through the back-side insulating film 31 (FIG. 6) to the back surface 20b of the substrate 20. The back windows can be cut by means of a laser or chemically etched with use, e.g., of a fixed shadow mask. No photolithography is needed in that case. The back windows 36a and 36b are relatively wide and may have a width in the range of 1 to 5 mm.

Step 7, which is shown in FIG. 9, comprises deposition of a front-side conductive layer 38a and a back-side conductive layer 38b of stacked metal layers or metal-containing conductive paste layers onto the front and back surfaces of the initial device structure in FIG. 8, respectively. In other words, the conductive metal or metal-containing paste layers that form the front-side conductive layer 38a are deposited onto the surface of the front-side nitride film (Si₃N₄ film) 28 and onto the surface of the front dopant-containing regions 24a and 24b exposed through the front windows 34a and 34b (FIG. 8), respectively. Similarly, the conductive metal or metal-containing paste layers that form the back-side conductive layer 38b are deposited onto the surface of the back-side nitride film (a Si₃N₄ film) 30 and onto the back surface of the substrate 20 exposed through the windows 36a and 36b (FIG. 8), respectively. The conductive metal layers used for the front surface can be silver, aluminum, titanium, palladium, nickel, or their combinations and are typically deposited (evaporated) onto the surface in the form of a stack, e.g., Ti—Ag, Ti—Pd—Ag, Ni—Cr, etc. The metal paste can be of a Ti—Ag-type, Ag—Al type, or other type known in the art. Conductive compositions for the back side can include metal layers of Al or Al—Ag, Al—Si, Al—Ag conductive paste, or the like. Compositions of the conductive layers on the front side and on the back side can be different, and these layers can be deposited simultaneously or in sequence. The conductive layers 38a and 38b may have a thickness in the range of 1 to 5 μm. Reference numerals 38b1 and 38b2 designate regions of the back-side conductive layer 38b, the regions being in direct contact with the substrate 20. The back-side conductive layer contains elements that during electrical and thermal treatment function as a back-side dopant to form selective BSF regions.

The broken line designated in FIG. 9 by reference numeral 38a1 shows that the conductive layer, e.g., the layer 38a, can consist of several consecutively applied sublayers. These sublayers can have different compositions.

It should be noted that Steps 1 through 7 are used to form the initial device structure as the basis for subsequent completion of the most critical elements of the solar cell by electrical and thermal means.

Step 8, which is shown in FIG. 10, comprises unique electrical and thermal processing of the structure shown in FIG. 9. In this step, the structure of FIG. 9 is placed into a fixture 40, which is shown in schematic form and is intended for electrical and thermal treatments of the structure, in particular, the areas of dopant-containing regions. The fixture is provided with a front-side current input electrode 42a, a front-side current output electrode 42b, a back-side current input electrode 44a, and a back-side current output electrode 44b. The current input and output electrodes are isolated from each other so that when current is applied to the input electrodes 42a and 44a, the applied current flows from the current input electrodes to the respective current output electrodes through the front-side conductive layer 38a and the back-side conductive layer 38b independently so that current of different magnitudes can pass through the front-side conductive layer 38a and the back-side conductive layer 38b.

In order to provide uniform distribution of the current density over the entire current-passing areas of the conductive layers, profiles of the electrodes 42a, 42b, 44a, and 44b should conform to the outlines of the substrate 20. When current flows through the conductive layers 38a and 38b, the material of the layers is heated by ohmic heating, which is also known as resistive heating. Thus, the temperature of the layers increases. The magnitude of current is selected so as to heat the treated layers to the temperature needed to cause diffusion of the dopant from the dopant-containing regions 24a and 24b (FIG. 9) and from the direct-contact regions 38b1 and 38b2 on the back side into the silicon substrate 20 (FIG. 9). As a result of the elevated temperature, the dopants further diffuse into the silicon substrate, thus forming selective emitters 24e, 24f on the front side and selective BSF regions 25a and 25b on the back side. Although only pairs of the selective-emitter regions and selective BSF regions are shown in FIG. 10, which is a cross-sectional view of the structure, in reality there is a plurality of such regions on both sides of the substrate 20, respectively.

In order to prevent dissipation of heat from zone 43 during electrical and thermal treatment, this zone can be confined between the thermal insulating walls 46a, 46b, 46c, and 46d. The temperature in the electrical and thermal zone 43 may be higher than the melting point of one or several sublayers of the conductive layer 38a and/or 38b. In order to prevent leakage of the molten material from the zone 43, this zone must be sealed with the thermal insulating walls 46c and 46d. In the process, the maximum temperature of the regions of the dopant diffusion should be in the range of 900 to 1000° C. for the front and 650 to 750° C. for the back. Because of the interaction of heat between the front and the back, it may be necessary to conduct the electrical and thermal treatment process for the front and back individually or simultaneously.

In the course of electrical and thermal treatment, the lower portion of the front-side conductive layer 38a interacts with the underlying dopant-containing regions 24a and 24b (FIG. 9) and with the selective emitters 24e, 24f (FIG. 10), whereby a metal-silicon alloy forms in the zone of contact between the interacting materials. On the other hand, interaction of the conductive material of the layer 38a with the Si₃N₄ film 28 is different from that in the areas of the selective emitters 24e and 24f. More specifically, the material of the lower portion of the layer 38a can be selected so that a compound functioning as a diffusion barrier for atoms of metal that can diffuse through the front-side insulating film 32 (FIG. 7) form as a result of interaction of the material of the layer 38a with the Si₃N₄ film 28. For example, if the lower portion of the layer 38a is made of titanium, then a titanium-nitride (TiN) compound is formed. Similar consideration can be applied to the back of the structure.

The front-side conductive layer 38a and the back-side conductive layer 38b can be subjected to the above-described electrical and thermal treatment simultaneously or separately. In selecting parameters for electrical and thermal treatment, one should consider the difference between the coefficients of thermal expansion of the silicon substrate and materials of the conductive layers. In order to secure the achieved structure and to ensure integrity of its layers for subsequent treatment, cooling is carried out in Step 8.

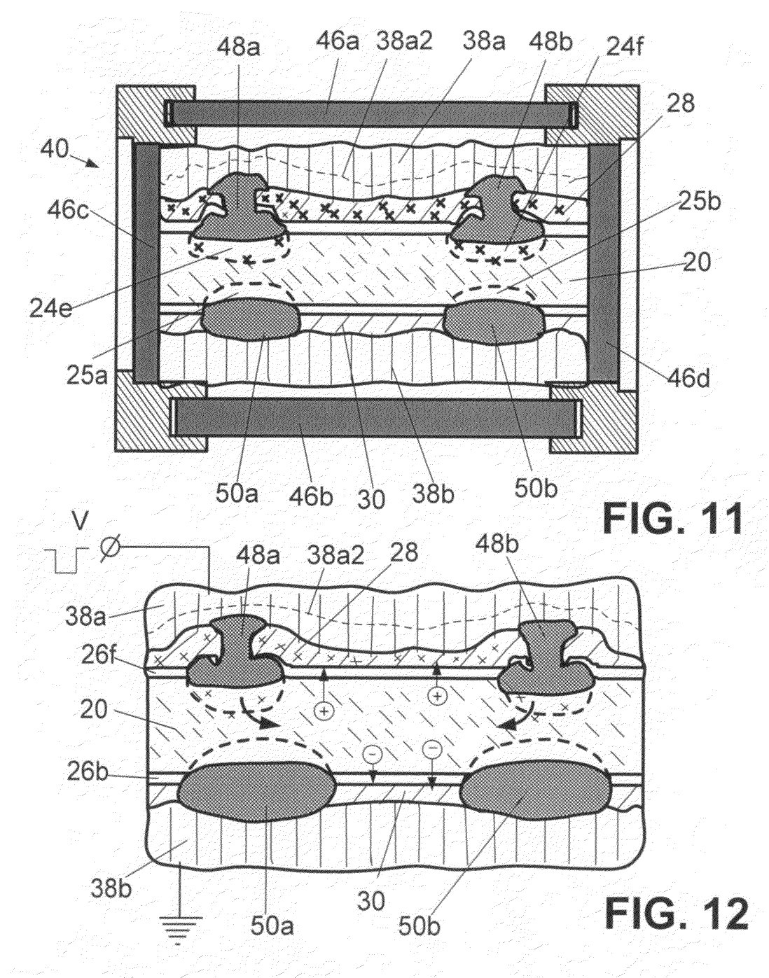

FIG. 11 is a cross-sectional view of the structure obtained after the critical Step 8. In other words, the structure shown in FIG. 11 is an intermediate structure obtained before the subsequent pulse electrical treatment, which is described below. Though the supply of current is discontinued, the structure can remain in the fixture 40 to the end of the manufacturing process. As a result of the electrical and thermal treatment described above, in addition to the aforementioned selective emitters 24e and 24f and the selective BSF regions 25a and 25b, alloyed regions, hereinafter referred to as selective-emitter contact regions 48a and 48b, are formed on the front side of the structure, and alloyed regions, hereinafter referred to as contacts to selective BSF regions 50a and 50b, are formed on the back side of the structure.

The aforementioned selective-emitter contact regions 48a and 48b, which may comprise, e.g., an Ag—Si alloy or Ti—Si alloy, and the contacts to selective BSF regions 50a and 50b, which may comprise, e.g., Al—Si alloy, are darkened in FIG. 9 and in all subsequent drawings. In the final solar cell product, these regions provide good Ohmic contacts to the functional areas of the cell, such as selective emitters and silicon substrate.

Diffusion that occurs in Step 8 may cause appearance of defects in N+-P junctions of the selective emitters. These defects, which can be caused by diffusion, e.g., of Ag, Ti, etc., into Si, are marked by “x” symbols in the selective-emitter regions 24e, 24f. Similarly, defects may also occur in the Si₃N₄ film 28 because of diffusion, e.g., of Ag. The defects in this region are also marked by symbol “x”. The conductive layers 38a and 38b that have uneven outer surfaces caused by electrical and thermal treatment still remain in the structure. Since during electrical and thermal treatment some sublayers of the conductive layers 38a and 38b may be fused and then solidified, different substructures may occur in the conductive layers 38a and 38b. This is shown in FIG. 9 by a broken line 38a2. It is important to note that electrical and thermal treatment does not significantly impair conductive properties, integrity, or adhesion of the conductive layers 38a and 38b to the underlying layers, such as the Si₃N₄ layer.

If necessary, some intermediate steps may be required after Step 8, such as chemical mechanical planarization, chemical etching and cleaning, or low-temperature annealing in a gaseous atmosphere.

FIG. 12 illustrates Step 9, which is pulse electrical treatment of the intermediate device structure of FIG. 9. For simplicity in FIG. 11 and in subsequent drawings, the fixture 40, in which the structure may remain to the end of the process, is not shown. In Step 9, voltage pulse or a sequence of voltage pulses V is applied between the front-side conductive layer 38a and the back-side conductive layer 38b. Regarding the P-type silicon substrate 20, the pulse V must have a negative polarity on the front side. Regarding the N-type silicon substrate 20 (which is not considered herein), the pulse V must have positive polarity on the front side.

As a result, fixed charges of opposite signs form on the front-side insulating film and on the back-side insulating film in order to form the field-induced emitter and the field-induced BSF region.

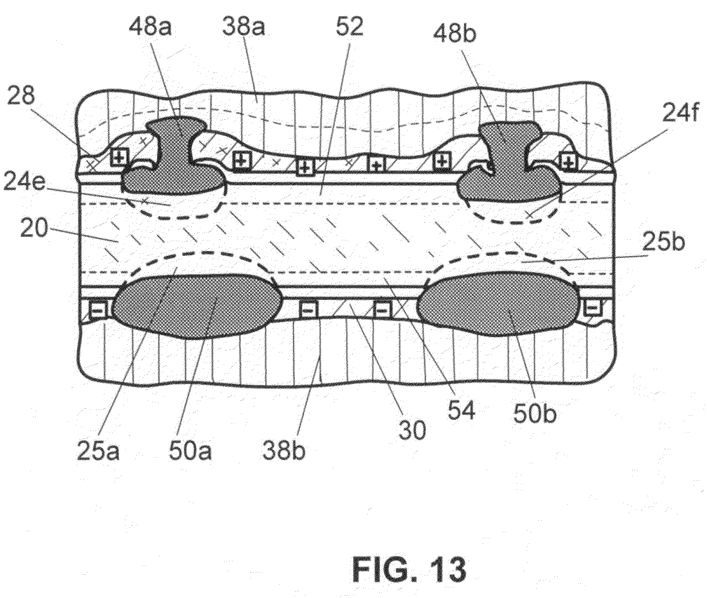

For the P-type silicon substrate 20, the pulse V causes holes (shown by symbols (+) in FIG. 12) to drift toward the front side and to enter the Si₃N₄ film 28 through the front SiO₂ layer 26f. At the same time, the pulse V causes the electrons (shown by symbols (−) in FIG. 12) to drift toward the back side and to enter the Si₃N₄ film 30 through the back-side SiO₂ layer 26b. As a result, a fixed positive charge is generated at or around the interface of the Si₃N₄ film 28 with the front-side SiO₂ layer 26f. Similarly, a fixed negative charge is generated at or around the interface of the Si₃N₄ film 30 with the back-side SiO₂ layer 26b. The fixed charges are not shown in FIG. 12 but are shown in FIG. 13.

Application of voltage pulse V of the above-described polarity causes flow of a forward current (shown by curved arrows in FIG. 12) through the N⁺-P junctions of selective emitters. It is assumed that the above current will eliminate all or a significant number of the above-mentioned defects in the selective emitters, thus improving quality of the selective emitter junctions.

The pulse may have the following parameters: V in the range of 20 to 100V (depending on Si-nitride thickness and other factors) and total duration in the range of 1 to 100 ms. If necessary, an embedded test structure can be used to check field-induced emitter (inversion) formation and N+-P junction quality.

FIG. 13 is a sectional view of the structure formed after completion of the pulse electrical treatment in Step 9. Once the fixed positive charge is introduced into the Si₃N₄ film 28, an N⁺-inversion layer 52 forms on the front side to create a field-induced emitter. In other words, in the final solar cell, this N⁺-inversion layer 52 functions as a field-induced emitter. At the same time and as a result of introduction of the fixed negative charge into the Si₃N₄ film 30, a P⁺-accumulation layer 54 forms on the back side to create a field-induced BSF region of the cell.

FIG. 1 shows the PV device D obtained after the last Step 10a, in which the front-side conductive layer 38a of the structure shown in FIG. 13 is removed (e.g., by a lift-off process). Since the selective emitter contact regions 48a and 48b have substantially stronger adhesion to the substrate 20, lift-off of the conductive layer 38a does not separate the conductive regions 48a and 48b from the selective emitters; therefore, after removal of the conductive layer 38a, the upper surfaces of the selective emitter contact regions 48a and 48b and the Si₃N₄ film 28 are exposed. In the solar cell, the selective emitter contact regions 48a and 48b function as front-side self-aligned electrodes.

In the example of the PV device D shown in FIG. 1, the back-side conductive layer 38b of the structure shown in FIG. 13 remains intact after step 10a and is used in the solar cell as a back-side electrode and a back reflector.

FIG. 2 shows a PV device D1 obtained according to another aspect of the invention as a result of Step 10b. In this modification, in addition to the front-side conductive layer 38a, the back-side conductive layer 38b is removed as well. As a result, contacts to the selective BSF regions are formed and are intended to function in the final device as back-side electrodes. In fact, FIG. 2 shows a front-side solar cell, which sometimes is referred to as a transparent solar cell.

If necessary, the outer surfaces of the solar cell obtained after Steps 10a and 10b may require some minor finishing operations, such as chemical or mechanical polishing, chemical cleaning, or electroplating of the electrode surfaces.

Given below is a specific example of parameters for the devices D and D1 in FIG. 1 and FIG. 2.

Silicon substrate 20 thickness: 150 to 300 μm; resistivity: 1 to 10 Ohm·cm

Electrical charge density in the insulating films 31 and 32: 2·10¹² to 5·10¹² carriers/cm²

Contact resistivity of contact regions 48a, 48b, 50a, 50b to selective emitters and to selective BSF regions, respectively: 0.1 to 1.0 mOhm/cm²

Distance between contact regions 48a, 48b: 0.5 to 1 mm.

Calculations showed that photovoltaic devices D and D1 of the type having the aforementioned parameters may generate the following PV outputs:
Short circuit current: 35 to 42 mA/cm²
Open circuit voltage: 0.65 to 0.75 V
Fill factor: 0.7 to 0.75
Power conversion efficiency: 16 to 23.5%.

Although the invention is shown and described with reference to specific examples, it is understood that these examples should not be construed as limiting the areas of application of the invention and that any changes and modifications are possible provided that these changes and modifications do not depart from the scope of the attached patent claims. For example, dopant substances may be other than those indicated in the specification. The fixture used for supply of current and for thermal insulation of the current-modified structure components may have various designs. The structures shown and described may relate not only to solar cells but to any other suitable electronic device. The silicon substrate may be of an N-type. In this case, the dopant substance of the front side should be a boron-containing composition, the back-side conductive film should contain the dopant source for forming a N+ type BSF regions, and the pulse V shown in FIG. 12 must have positive polarity on the front side. Also, the device structure in FIGS. 1 and 2 can be reversed (with the exception of the back-side conductive layer) so that the field-induced emitters and selective emitters can be formed on the back side of the silicon substrate while the field-induced front surface field regions and selective front surface field regions are formed on the front-side surface, which is the case for back-side solar cells. In this case, back-side conductive layers remain on the back side of the device.

1. A silicon-based photovoltaic device produced by essentially electrical means comprising at least the following components:
silicon substrate having a first side and a second side;
field-induced emitter that is formed in the silicon substrate on the first side and comprises an inversion layer;
at least one selective emitter formed in the silicon substrate on the first side thereof;
first insulating film that is formed on the first side of the silicon substrate and contains an electric charge of a first sign intended for generating said inversion layer;
at least one contact region to said at least one selective emitter;
field-induced BSF region that is formed in the silicon substrate on the second side and comprises an accumulation layer;
at least one selective BSF region formed in the silicon substrate on the second side thereof;
second insulating film that is formed on the second side of the silicon substrate and contains an electrical charge of a second sign, which is opposite to said first sign and is intended for generating the accumulation layer; and
at least one contact region to said at least one selective BSF region.

2. The device of claim 1, further comprising a back-side conductive layer located on one side of the silicon substrate.

3. The device of claim 1, wherein the first insulating film comprises at least a silicon oxide layer and silicon nitride layer, wherein the silicon nitride layer contains said electrical charge of a first sign, and the silicon oxide film is a barrier that prevents leaking of the electric charge of a first sign to the silicon substrate.

4. The device of claim 2, wherein the first insulating film comprises at least a silicon oxide layer and silicon nitride layer, wherein the silicon nitride layer contains said electrical charge of a first sign, and the silicon oxide film is a barrier that prevents leaking of the electrical charge of a first sign to the silicon substrate.

5. The device of claim 1, wherein the field-induced emitter, said at least one selective emitter, said at least one contact region to said at least one selective emitter, the field-induced BSF region, said at least one selective BSF region, said at least one contact region to said at least one selective BSF region, the electrical charge of a first sign and the electrical charge of a second sign are formed by mean of electrical and thermal treatment.

6. The device of claim 5, wherein the electrical charge of a first sign and the electrical charge of a second sign are charges that are formed simultaneously by mean of an electrical pulse.

7. The device of claim 1, wherein said at least one contact region to said at least one selective emitter and said at least one contact region to said at least one selective BSF region comprise alloys that are formed during said electrical and thermal treatment.

8. The device of claim 2, wherein said at least one contact region to said at least one selective emitter and said at least one contact region to said at least one selective BSF region comprise alloys that are formed during said electrical and thermal treatment.

9. The device of claim 3, wherein said at least one contact region to said at least one selective emitter and said at least one contact region to said at least one selective BSF region comprise alloys that are formed during said electrical and thermal treatment.

10. The device of claim 2, wherein said device comprises a front-side solar cell and wherein the back-side conductive layer is a back reflector.

11. The device of claim 2, wherein the field-induced emitter, said at least one selective emitter, said at least one contact region to said at least one selective emitter, the field-induced BSF region, said at least one selective BSF region, said at least one contact region to said at least one selective BSF region, the electrical charge of a first sign, and the electrical charge of a second sign are formed by mean of electrical and thermal treatment.

12. The device of claim 11, wherein the electrical charge of a first sign and the electrical charge of a second sign are charges that are formed simultaneously by mean of an electrical pulse.

13. The device of claim 1, wherein the electrical charge of a first sign and the electrical charge of a second sign are in the range of 2·10¹² to 5·10¹² carriers/cm².

14. The device of claim 1, wherein the electrical charge of a first sign and the electrical charge of a second sign are in the range of 2·10¹² to 5·10¹²carriers/cm².

15. The device of claim 3, wherein the electrical charge of a first sign and the electrical charge of a second sign are in the range of 2·10¹² to 5·10¹² carriers/cm².

16. A silicon-based photovoltaic device produced by essentially electrical means comprising at least the following components:
silicon substrate having a first side and a second side;
field-induced emitter that is formed in the silicon substrate on the first side and comprises an inversion layer;
plurality of selective emitters formed in the silicon substrate on the first side thereof;
first insulating film that is formed on the first side of the silicon substrate and contains an electrical charge of a first sign intended for generating said inversion layer;
contact region to each selective emitter of said plurality;
field-induced BSF region that is formed in the silicon substrate on the second side and comprises an accumulation layer;
plurality of selective BSF regions formed in the silicon substrate on the second side thereof;
second insulating film that is formed on the second side of the silicon substrate and contains an electric charge of a second sign, which is opposite to said first sign and is intended for generating the accumulation layer; and
contact region to each selective BSF region of said plurality.

17. The device of claim 16, further comprising a back-side conductive layer located on one side of the silicon substrate.

18. The device of claim 16, wherein the first insulating film comprises at least a silicon oxide layer and silicon nitride layer, wherein the silicon nitride layer contains said electrical charge of a first sign, and the silicon oxide film is a barrier that prevents leaking of the electrical charge of a first sign to the silicon substrate.

19. The device of claim 18, wherein the field-induced emitter, the selective emitters, the contact regions to the selective emitters, the field-induced BSF region, the selective BSF regions, the contact regions to the selective BSF regions, the electrical charge of a first sign, and the electrical charge of a second sign are formed by mean of electrical and thermal treatment, wherein the electrical charge of a first sign and the electrical charge of a second sign are charges that are formed simultaneously by mean of an electrical pulse.

20. The device of claim 19, wherein the contact regions to the selective emitters and the contact regions to the selective BSF regions comprise alloys that are formed during said electrical and thermal treatment.
